(19) United States
(12) Patent Application Publication
(10) Pub. No.: US 2024/0128985 A1
(43) Pub. Date: Apr. 18, 2024

(54) DECODING DEVICE AND DECODING METHOD USING LOW-DENSITY PARITY CHECK CODE INCLUDING CODE DIFFERENT FROM SINGLE PARITY CHECK CODE

(71) Applicant: SAMSUNG ELECTRONICS CO., LTD., Suwon-si (KR)

(72) Inventors: Bohwan Jun, Suwon-si (KR); Daeyeol Yang, Suwon-si (KR); Hongrak Son, Suwon-si (KR); Geunyeong Yu, Suwon-si (KR); Youngjun Hwang, Suwon-si (KR)

(73) Assignee: SAMSUNG ELECTRONICS CO., LTD., Suwon-si (KR)

(21) Appl. No.: 18/242,834

(22) Filed: Sep. 6, 2023

(30) Foreign Application Priority Data
Sep. 30, 2022 (KR) 10-2022-0125817

(51) Int. Cl. H03M 13/11; H03M 13/00

(52) U.S. Cl. CPC H03M 13/1105; H03M 13/6575

(57) ABSTRACT

A decoding device and a decoding method which relate to: receiving a codeword; estimating a number of errors included in the received codeword; and decoding the codeword based on the estimated number of errors using at least one of a first parity check matrix and a second parity check matrix, wherein the first parity check matrix corresponds to a first low-density parity check (LDPC) code, and the second parity check matrix corresponds to a second LDPC code, and wherein the first parity check matrix is based on a first code type, and the second parity check matrix is based on a second code type different from the first code type.

### CROSS-REFERENCE TO RELATED APPLICATION

This application is based on and claims priority under 35 U.S.C. § 119 to Korean Patent Application No. 10-2022-0125817, filed on Sep. 30, 2022, in the Korean Intellectual Property Office, the disclosure of which is incorporated by reference herein in its entirety.

### BACKGROUND

### 1. Field

The disclosure relates to a decoding method using a low-density parity check (LDPC) code including a code different from a single parity check (SPC) code.

### 2. Description of Related Art

In a non-volatile memory, such as a solid-state device (SSD), when the number of bits stored in one cell increases, the reliability of the non-volatile memory may deteriorate. Accordingly, an error correction code (ECC) capable of overcoming this problem may be used.

An ECC capable of detecting errors related to data transmission may also be used in a wireless communication system in which fading and Doppler spreading occur. As a data throughput in the wireless communication system increases, a more powerful ECC may be used.

Therefore, there is a need for a decoding device and decoding method which may maximize correction capability while minimizing complexity.

### SUMMARY

Provided is a decoding device and decoding method using a low-density parity check (LDPC) code including a code different from a single parity check (SPC) code.

Additional aspects will be set forth in part in the description which follows and, in part, will be apparent from the description, or may be learned by practice of the presented embodiments.

In accordance with an aspect of the disclosure, a decoding method includes receiving a codeword; estimating a number of errors included in the received codeword; and decoding the codeword based on the estimated number of errors using at least one of a first parity check matrix and a second parity check matrix, wherein the first parity check matrix corresponds to a first low-density parity check (LDPC) code, and the second parity check matrix corresponds to a second LDPC code, and wherein the first parity check matrix is based on a first code type, and the second parity check matrix is based on a second code type different from the first code type.

In accordance with an aspect of the disclosure, a decoder includes a memory configured to store at least one decoding parameter; and at least one processor operatively connected to the memory, and configured to: receive a codeword, estimate a number of errors in the received codeword, and decode the codeword based on the estimated number of errors using at least one of a first parity check matrix and a second parity check matrix, wherein the first parity check matrix corresponds to a first low-density parity check (LDPC) code, and the second parity check matrix corresponds to a second LDPC code, and wherein the first parity check matrix is based on a first code type, and the second parity check matrix is based on a second code type different from the first code type.

In accordance with an aspect of the disclosure, a memory controller includes a memory configured to store at least one decoding parameter; and an error correction circuit configured to: receive a codeword, estimate a number of errors in the received codeword, and decode the codeword based on the estimated number of errors using at least one of a first parity check matrix and a second parity check matrix, wherein the first parity check matrix corresponds to a first low-density parity check (LDPC) code, and the second parity check matrix corresponds to a second LDPC code, wherein the first parity check matrix is based on a first code type, and the second parity check matrix is based on a second code type different from the first code type.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of a memory system according to embodiments;

FIG. 2 is a block diagram of a decoder according to embodiments;

FIG. 3 is a block diagram of an operation of a decoder according to embodiments;

FIG. 4 illustrates a system according to embodiments;

FIG. 5 illustrates a parity check matrix according to embodiments;

FIG. 6 is a graph according to an embodiment;

FIG. 7 illustrates an operation sequence of a decoder according to embodiments;

FIG. 8 illustrates an operation sequence of a decoder according to embodiments;

FIG. 9 illustrates an operation sequence of a decoder according to embodiments;

FIG. 10 illustrates an operation sequence of a decoder according to embodiments; and

FIG. 11 illustrates a decoder according to embodiments.

### DETAILED DESCRIPTION

Hereinafter, embodiments will be described in detail with reference to the accompanying drawings.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

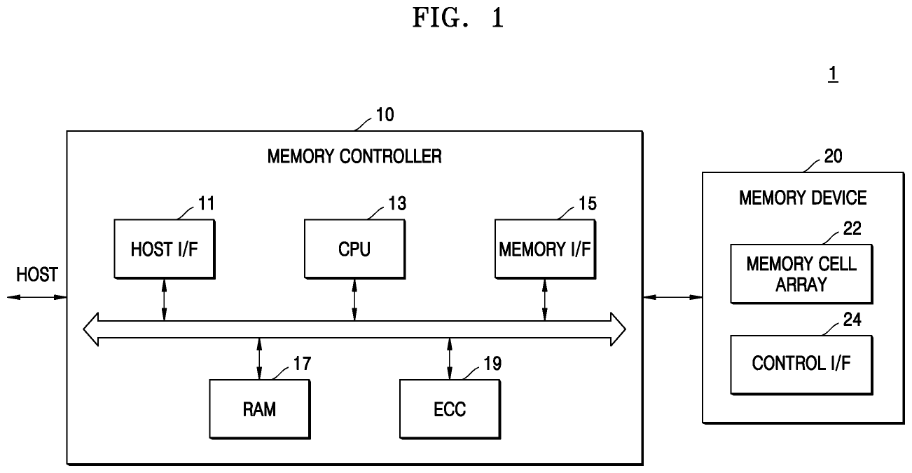

FIG. 1 is a block diagram of a memory system 1 according to embodiments.

Referring to FIG. 1, the memory system 1 may include a memory controller and a memory device 20.

The memory system 1 may correspond to any one of data storage media, which is based on a non-volatile memory. In embodiments, the memory system 1 may correspond to, for example, a memory card, a universal serial bus (USB) memory, and a solid state drive (SSD), however embodiments are not limited thereto.

The memory device 20 may include a memory cell array 22 and a control interface (I/F) 24 configured to transmit and receive data to and from the memory controller 10. The memory cell array 22 may be a two-dimensional (2D) structure (or a horizontal structure), which is formed in a lateral direction with respect to a substrate or a three-dimensional (3D) structure (or a vertical structure), which is formed in a vertical direction with respect to the substrate. A memory cell in the memory cell array 22 may be a non-volatile memory cell. For example, the memory cell array 22 may be a NAND flash memory cell array or a NOR flash memory cell array. Hereinafter, embodiments will be described in detail with reference to an example in which a plurality of memory cells are flash memory cells. However, embodiments not limited thereto. For example, in embodiments, the plurality of memory cells may be resistive memory cells, such as resistive random access memory (RRAM) memory cells, phase-change RAM (PRAM) memory cells, or magnetic RAM (MRAM) memory cells.

The memory controller 10 may control a memory operation on the memory device 20 in response to the request of a host HOST. In embodiments, the memory operation may be or include at least one of a write operation (which may be referred to as a program operation), a read operation, and an erase operation, however embodiments are not limited thereto. The memory controller 10 may include a host I/F 11, a central processing unit (CPU) (or a processor) 13, a memory I/F 15, random access memory (RAM) 17, and an error correction code (ECC) logic 19.

The memory controller 10 may transmit and receive data to and from the host HOST using the host I/F 11, and may transmit and receive data to and from the memory device 20 using the memory I/F 15. The host I/F 11 may be connected to the host HST through a connection such as a parallel advanced technology attachment (PATA) bus, a serial ATA (SATA) bus, a small computer system interface (SCSI), a universal serial bus (USB), and/or a peripheral component interconnection express (PCIe). The CPU 13 may control operations of the memory device 20, for example a write operation, a read operation, and a file system management operation. The RAM 17 may operate under the control of the CPU 13 and be used as a work memory, a buffer memory, and/or a cache memory. When the RAM 17 is used as the work memory, data processed by the CPU 13 may be temporarily stored in the RAM 17. When the RAM 17 is used as the buffer memory, the RAM 17 may be used to buffer data that is to be transmitted from the host HOST to the memory device 20 or transmitted from the memory device 20 to the host HOST. Furthermore, when the ECC logic 19 encodes data received from the host HOST or decodes a codeword received from the memory device 20, the RAM 17 may be used as a buffer for encoding and decoding operation.

The ECC logic 19 may receive the codeword from the memory device 20 and perform an error correction decoding operation on the received codeword. Due to deterioration of the memory cells in the memory cell array 22 and noise related to a memory operation, the codeword received by the ECC logic 19 from the memory device 20 may include a failed bit. The ECC logic 19 may correct an error in the codeword and provide the host HOST with data of which integrity is ensured.

In embodiments, the ECC logic 19 may decode the codeword based on a low-density parity check (LDPC) code. For example, in embodiments the LDPC code may be an example of an ECC used by the ECC logic 19. The LDPC code may be a type of linear block code that may repeatedly perform decoding. The LDPC code may be defined by a parity check matrix. The LDPC code may be a code with relatively few ones (is) in elements of the parity check matrix defining the LDPC code. The LDPC code may be used in a wireless communication system and a storage system because the LDPC code may have excellent correction capability with low complexity. Hereinafter, an operation of the ECC logic 19 will be described centering on the parity check matrix corresponding to the LDPC code. In an example described below, the codeword may be a data set having a size unit that may be decoded by using one parity check matrix corresponding to the LDPC code. In addition, the codeword may include sub-codewords, and a size unit of the sub-codeword may be less than or equal to a size unit of data transmitted by the memory controller 10 to the host HOST in response to a read request.

A condition of a check node of the LDPC code may be one where the check node becomes zero (0) in an exclusive OR (XOR) operation on all participant bits. A code that satisfies the above-described condition may be referred to as a single parity check (SPC) code. The LDPC code may be implemented through a decoding algorithm that delivers a message between a variable node and a check node.

A generalized-LDPC (G-LDPC) code may be a code which extends a concept of the LDPC code. In the G-LDPC code, single or heterogeneous codes may be used as a condition. The G-LDPC code may use, as a condition, a binary code including at least one of an SPC code, a Hamming code, an extended Hamming code, a Bose-Chaudhuri-Hocquenghem (BCH) code, and a polar code. In addition, the G-LDPC code may use, as a condition, a non-binary code including at least one of a Reed-Solomon (RS) code and a non-binary LDPC code. As compared to the LDPC code, in the case of the G-LDPC code, each bit of the codeword may be required to satisfy a complex condition. Accordingly, the G-LDPC code may have stronger correction capability than the LDPC code. For example, as compared to the LDPC code, the G-LDPC code may have characteristics such as a large minimum Hamming distance, high iterative decoding performance, high decoding convergence speed, and low error-floors.

In an embodiment, the ECC logic 19 may decode the codeword by using the G-LDPC code. For example, in embodiments the G-LDPC code may be an example of an ECC used by the ECC logic 19. In an example, the ECC logic 19 may receive a codeword, estimate the number of errors in the received codeword, and decode the codeword based on the estimated number of errors by using at least one of a first parity check matrix and a second parity check matrix. The first parity check matrix may be a parity check matrix of a first LDPC code, and the second parity check matrix may be a parity check matrix of a second LDPC code. The first parity check matrix may be based on an SPC code, and the second parity check matrix may be based on a code different from the SPC code.

Moreover, to enable rapid decoding in the future, the memory controller 10 may reorder the codeword, which is generated as a result of an encoding operation of the ECC logic 19, and provide the reordered codeword to the memory device 20. The memory device 20 may store the reordered codeword in the memory cell array 22 and provide the reordered codeword to the memory controller 10 in response to or based on a read command from the memory controller 10. In an embodiment, to enable rapid decoding in the future, the memory controller 10 may previously or pre-emptively reorder data before the ECC logic 19 performs the encoding operation. Furthermore, to enable rapid decoding in the future, the memory device 20 may reorder the stored codeword and output the stored codeword to the memory controller 10 before outputting the stored codeword in response to the read command from the memory controller 10. As described above, the memory controller 10 or the memory device 20 may efficiently perform a decoding operation by reordering the codeword in consideration or anticipation of a rapid decoding operation in the future.

The memory controller 10 according to an embodiment may perform any one of partial decoding and joint decoding, based on the number of errors in the codeword. Partial decoding may refer to a decoding scheme that provides a relatively high decoding speed and consumes low power by using only an LDPC code having an SPC code as a condition. Joint decoding may refer to a decoding scheme using not only an LDPC code but also a G-LDPC code having, as a condition, a code having a minimum Hamming distance of about 3 or more to provide relatively high decoding performance.

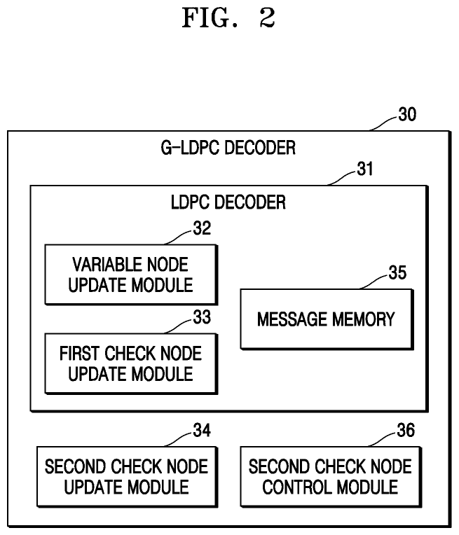

In some embodiments, the memory controller 10 may have a big/little architecture in relation to the decoding of the G-LDPC code. Based on the number of errors in the codeword being less than a predetermined number, the memory controller 10 may perform partial decoding by using an LDPC decoder operating with low power, that is, a little decoder related to an SPC code. Based on the number of errors in the codeword being equal to or greater than the reference number, the memory controller 10 may operate with high performance and perform joint decoding by adaptively using a joint decoder. The joint decoder may refer to a G-LDPC decoder including a LDPC decoder, an example of which is described below with reference to FIG. 2. Accordingly, an effect of reducing an area or a gate count may be obtained.

FIG. 2 is a block diagram of a decoder according to embodiments.

Referring to FIG. 2, a G-LDPC decoder 30 may include an LDPC decoder 31, a second check node update module 34, and a second check node control module 36.

In some embodiments, the G-LDPC decoder 30 may be included in the ECC logic 19 of FIG. 1.

The LDPC decoder 31 may include a variable node update module 32, a first check node update module 33, and a message memory 35.

The variable node update module 32 may calculate a message by using messages respectively received from the first check node update module 33 and the second check node update module 34 and a value received from the outside.

The first check node update module 33 may calculate a message that satisfies a single parity check (SPC) condition. The first check node update module 33 may perform an operation on a first check node such that a parity check matrix satisfies the SPC code condition. The second check node update module 34 may calculate a message that satisfies an SPC code and a code condition that is different from the SPC code. The second check node update module 34 may perform an operation on a second check node such that the parity check matrix satisfies at least one of the SPC code and a code different from the SPC code. The second check node may be referred to as a super check node (SCN). The second check node update module 34 may receive a soft message and calculate the soft message to satisfy a generalized constraint. Thereafter, the second check node update module 34 may output the calculated soft message. That is, the second check node update module 34 may be based on soft in soft out (SISO).

At least one of the variable node update module 32, the first check node update module 33, and the second check node update module 34 may update a message by using a chase algorithm.

The second check node control module 36 may control the second check node update module 34 and adjust an output message of the second check node update module 34. The second check node control module 36 may adaptively determine whether to use the second check node update module 34, based on a connection state of the parity check matrix H, the estimated number of errors, the number of update iterations, a decoding middle-progress state, and an update period. Also, the second check node control module 36 may adaptively adjust a size of the output message of the second check node update module 34, based on the connection state of the parity check matrix H, the estimated number of errors, the number of iterations, the decoding middle-progress state, and the update period.

An initial value of the variable node update module 32 may be hard decision data or soft decision data. In an LDPC decoding process, a process of exchanging messages that are respectively created and updated by a variable node and check nodes on a Tanner graph may be repeated.

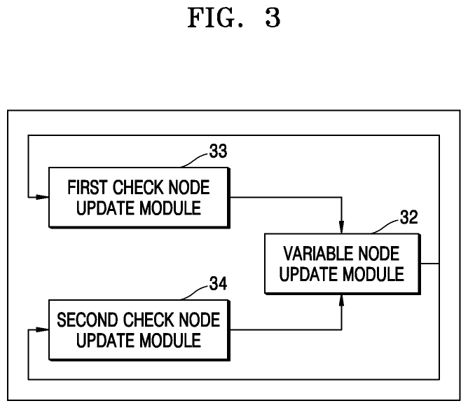

FIG. 3 is a block diagram of an operation of a decoder according to embodiments. FIG. 3 is described below with reference to FIGS. 1 and 2.

Referring to FIG. 3, each of a first check node update module 33 and a second check node update module 34 may receive soft information from a variable node update module 32 and calculate new soft information by using the received soft information.

The variable node update module 32 may receive hard decision information or soft decision information from the memory device 20. The variable node update module 32 may joint or join the hard decision information or soft decision information received from the memory device 20, and soft information received from each of the first check node update module 33 and the second check node update module 34, and may generate new soft information.

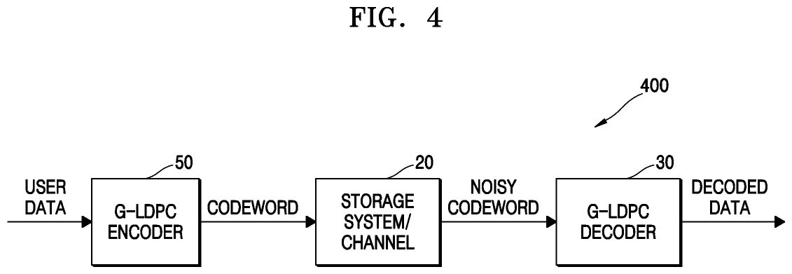

FIG. 4 illustrates a system according to embodiments.

As shown in FIG. 4, a system 400 may include a G-LDPC encoder 50, a storage system/channel 20, and a G-LDPC decoder 30. In embodiments, one or both of the G-LDPC encoder 50 and the G-LDPC decoder 30 of FIG. 4 may be included in the ECC logic 19 of FIG. 1.

Referring to FIG. 4, as an example the G-LDPC encoder 50 may receive input data and code the input data into a codeword. The G-LDPC encoder 50 may transmit the codeword to a memory device included in the storage system/channel 20, or across a communication channel included in the storage system/channel 20. As a result of noise included in or corresponding to the storage system/channel 20, the G-LDPC decoder 30 may receive a noisy codeword which corresponds to the codeword generated by the G-LDPC encoder 50. The G-LDPC decoder 30 may decode the noisy codeword and generate output data which corresponds to the input data.

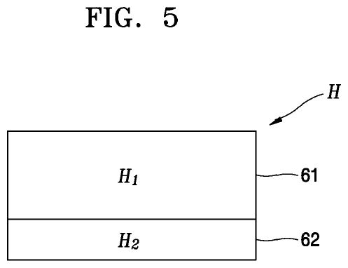

FIG. 5 illustrates a parity check matrix H according to embodiments.

Referring to FIG. 5, a parity check matrix H of a G-LDPC code may include a first parity check matrix 61, illustrated as H₁, and a second parity check matrix 62, illustrated as Hz. The first parity check matrix 61 may be a parity check matrix of a binary LDPC code, and may correspond to an SPC code. The second parity check matrix 62 may be a parity check matrix of a G-LDPC code. The second parity check matrix 62 may be a parity check matrix corresponding to various codes including an SPC code. Accordingly, a minimum Hamming distance of the second parity check matrix H₂ may be about 3 or more. In a decoding process, the first parity check matrix 61 and the second parity check matrix 62 may be partially jointed or joined, and processed.

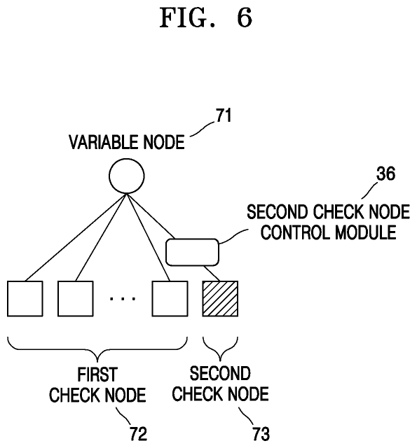

FIG. 6 shows a graph according to an embodiment. FIG. 6 is described below with reference to FIGS. 2 and 3.

An LDPC code may be depicted by a Tanner graph (or a bipartite graph) including a variable node corresponding to a bit of a codeword, a check node, which is a condition to be satisfied by the variable node, and an edge connecting the variable node and the check node. The LDPC code may be depicted by a Tanner graph that visually shows a parity check matrix H in a decoding process. In the Tanner graph, rows of the parity check matrix H may be defined by M check nodes (where M is a positive integer), and columns of the parity check matrix H may be defined by N variable nodes (where N is a positive integer).

A condition of the check node of the LDPC code may be one where the check node becomes or produces zero (0) as a result of an exclusive OR (XOR) operation on all participant bits. A code that satisfies the above-described condition may be referred to as an SPC code. The LDPC code may be implemented through a decoding algorithm that delivers a message between the variable node and the check node.

As discussed above, a G-LDPC code may be a code which extends a concept of the LDPC code. In the G-LDPC code, single codes or heterogeneous codes may be used as a condition. The G-LDPC code may use, as a condition, a binary code including at least one of an SPC code, a Hamming code, an extended Hamming code, a BCH code, and a polar code. The G-LDPC code may use, as a condition, a non-binary code including at least one of an RS code and a non-binary LDPC code. In the case of the G-LDPC code, each bit of the codeword may be required to satisfy a more complex condition than in the LDPC code.

Referring to FIG. 6, a plurality of first check nodes 72 and a second check node 73 may correspond to one variable node 71. Each of the first check nodes 72 may refer to a check node of the LDPC code using the SPC code as a condition. The second check node 73 may refer to a check node of the G-LDPC code having, as a condition, at least one of the SPC code and codes different from the SPC code. Although FIG. 6 illustrates only one variable node 71 and one second check node 73 for convenience of description, in embodiments a plurality of variable nodes 71 and a plurality of second check nodes 73 may be provided. A second check node control module 36 may control an output message of the second check node 73. For example, the second check node control module 36 may adaptively control a size of a message of the second check node 73 based on the number of errors, and determine whether to use the second check node 73. For example, based on the number of errors being greater than or equal to a reference value, the second check node control module 36 may determine to use the message of the second check node 73 and control the size of the message of the second check node 73.

An example of updating the variable node 71 is provided below.

A message transmitted from the variable node 71 to the first check node 72 may be expressed as in Equation 1:

m_{v→c}=LLRᵥ+Σ_{c′∈} [symbol] _{(v)\c}m_{c′→v}+F(m_{s→v}) (Equation 1)

In Equation 1 m_{v→c} may denote the message transmitted from the variable node 71 to the first check node 72, LLRᵥ may denote a logic likelihood ratio (LLR) of the variable node 71, m_{c′→v} may denote a message from the first check node 72 excepting a check node c to the variable node 71, [symbol] (v) may denote a set of check nodes adjacent to the variable node 71, m_{s→v} may denote a message transmitted from the second check node 73 to the variable node 71, and F(m_{s→v}) may denote a message transmitted from the second check node 73, which is controlled, to the variable node 71.

A message transmitted from the variable node 71 to the second check node 73 may be expressed as in Equation 2:

m_{v→s}=LLRᵥ+Σ_{c∈} [symbol] ₍ᵥ₎m_{c→v} (Equation 2)

In Equation 2, m_{v→s} may denote a message transmitted from the variable node 71 to the second check node 74. m_{c→v} may denote a message transmitted from the first check node 72 to the variable node 71.

A value for determining whether the variable node 71 is zero (0) or one (1) may be expressed as in Equation 3:

APPᵥ=LLRᵥ+Σ_{c∈} [symbol] ₍ᵥ₎m_{c→v}+F(m_{s→v}) (Equation 3)

In Equation 3, APPᵥ may denote the value for determining whether the variable node 71 is 0 or 1.

Referring to FIG. 6, a G-LDPC decoder 30 according to an embodiment may be a decoder obtained by adding, to an LDPC decoder 31, a check node of a code different form the SPC code.

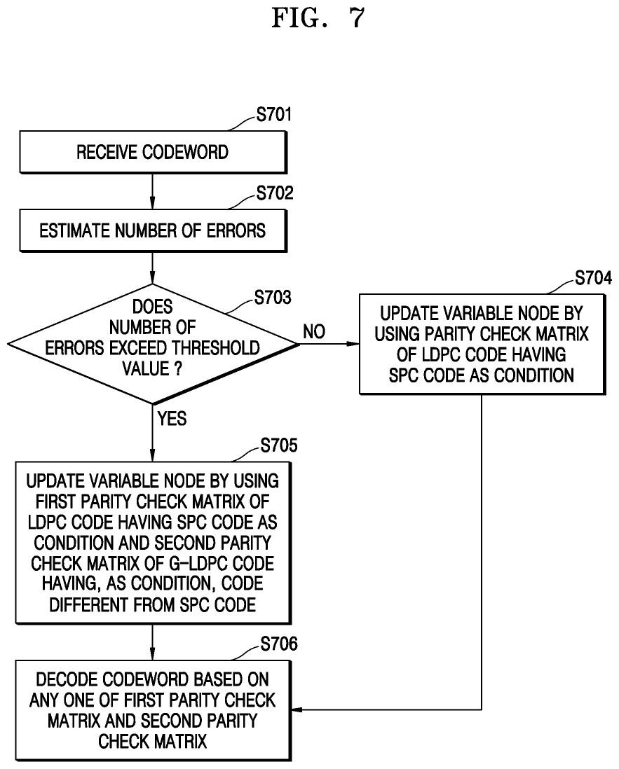

FIG. 7 illustrates an operation sequence of a decoder according to embodiments. FIG. 7 is described below with reference to FIGS. 1 and 2. In embodiments, the decoder may correspond to, for example, a decoder included in the ECC logic 19, for example the G-LDPC decoder 30.

In operation S701, the decoder may receive a codeword. For example, the decoder may receive the codeword from a memory device 20.

In operation S702, the decoder may estimate the number of errors. For example, the decoder may estimate the number of bits in which errors have occurred, in the received codeword.

In operation S703, the decoder may determine whether the number of errors exceeds a threshold value. For example, the decoder may determine whether the number of bits in which errors have occurred exceeds a threshold value. In embodiments, the threshold value may be predetermined, adaptively determined by the decoder according to the circumstances, or received from an outside, for example from an outside of the G-LDPC decoder 30, an outside of the ECC logic 19, or an outside of the memory controller 10.

In operation S704, based on the number of errors not exceeding the threshold value (NO at operation S703), the decoder may update a variable node by using a parity check matrix of an LDPC code having an SPC code as a condition. Also, the decoder may not use a parity check matrix of a G-LDPC code having, as a condition, a code different from the SPC code. That is, the decoder may update the variable node by using only the parity check matrix of the LDPC code having the SPC code as the condition. In an example, the decoder may turn off a second check node update module 34.

In operation S705, based on the number of errors exceeding the threshold value (YES at operation S703), the decoder may update the variable node by using a third parity check matrix, which includes a first parity check matrix of an LDPC code having an SPC code as a condition and a second parity check matrix of a G-LDPC code having, as a condition, a code different from the SPC code. In an example, the decoder may turn on the second check node update module 34.

In operation S706, the decoder may decode the codeword based on any one of the first parity check matrix and the third parity check matrix. Specifically, the decoder may update the variable node by using only the first parity check matrix of the LDPC code having the SPC code as the condition. In embodiments, the decoder may update the variable node by simultaneously using the first parity check matrix of the LDPC code having the SPC code as the condition and the second parity check matrix of the G-LDPC code having, as the condition, the code different from the SPC code. For example, based on the number of errors in the codeword, the decoder may perform partial decoding by using only the LDPC code having the SPC code as the condition, or perform joint decoding by simultaneously using the LDPC code having the SPC code as the condition and the G-LDPC code having, as the condition, the code different from the SPC code.

In some embodiments corresponding to NAND flash, partial decoding may be performed because there are relatively few errors at most read requests. Accordingly, the average power consumption may be reduced. When the number of errors is large, joint decoding may be performed. As a result, relatively powerful error correction may be performed.

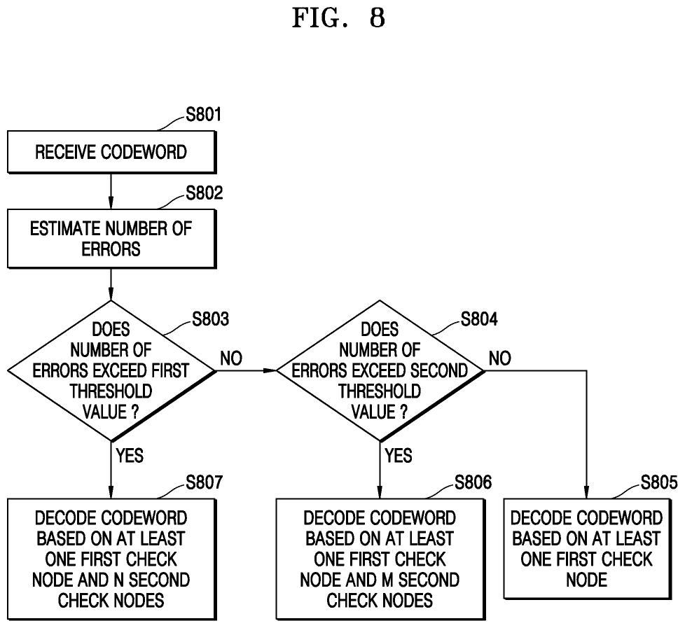

FIG. 8 illustrates an operation sequence of a decoder according to embodiments. FIG. 8 is described below with reference to FIGS. 5 and 6. In embodiments, the decoder may correspond to, for example, a decoder included in the ECC logic 19, for example the G-LDPC decoder 30.

In operation S801, the decoder may receive a codeword. For example, the decoder may receive the codeword from a memory device 20.

In operation S802, the decoder may estimate the number of errors. For example, the decoder may estimate the number of bits in which errors have occurred, in the received codeword.

In operation S803, the decoder may determine whether the number of errors exceeds a first threshold value. For example, the decoder may determine whether the number of bits in which errors have occurred exceeds the first threshold value. The first threshold value may be predetermined, adaptively determined by the decoder according to the circumstances, or received from the outside, for example from the outside of the G-LDPC decoder 30, the outside of the ECC logic 19, or the outside of the memory controller 10.

In operation S804, based on the number of errors not exceeding the first threshold value (NO at operation S803), the decoder may determine whether the number of errors exceeds a second threshold value. The second threshold value may be predetermined, adaptively determined by the decoder according to the circumstances, or received from the outside, for example from the outside of the G-LDPC decoder 30, the outside of the ECC logic 19, or the outside of the memory controller 10. The first threshold value may be greater than the second threshold value.

In operation S805, based on the number of errors not exceeding the second threshold value (NO at operation S804), the decoder may decode the codeword based on at least one first check node 72. Specifically, based on the number of errors not exceeding the second threshold value, the decoder may decode the codeword by using only a first parity check matrix 61 of an LDPC code having an SPC code as a condition.

In operation S806, based on the number of errors exceeding the second threshold value (YES at operation S804), the decoder may decode the codeword based on the at least one first check node 72 and M second check nodes 73. Here, M may be an integer of 1 or more. For example, based on the number of errors not exceeding the first threshold value and exceeding the second threshold value, the decoder may decode the codeword by using the first parity check matrix 61 of the LDPC code having the SPC code as the condition and a second parity check matrix 62 of a G-LDPC code having, as a condition, a code different from the SPC code. The number of check nodes of the second parity check matrix 62 may be M.

In operation S807, based on the number of errors exceeding the first threshold value (YES at operation S803), the decoder may decode the codeword based on at least one first check node and N second check nodes. For example, based on the number of errors exceeding the second threshold value, the decoder may decode the codeword by simultaneously using the first parity check matrix 61 of the LDPC code having the SPC code as the condition and a second parity check matrix 62 of a G-LDPC code having, as a condition, at least one of the SPC code and codes that are different from the SPC code. Here, the number of check nodes of the second parity check matrix 62 may be N. N may be an integer greater than M.

As described above, the decoder may determine which decoding operation from among partial decoding and joint decoding to perform, based on the number of errors. In addition, when the decoder performs joint decoding, the decoder may determine, based on the number of errors, the number of check nodes of a parity check matrix of a G-LDPC code having, as a condition, a code with a minimum Hamming distance other than that of the SPC code.

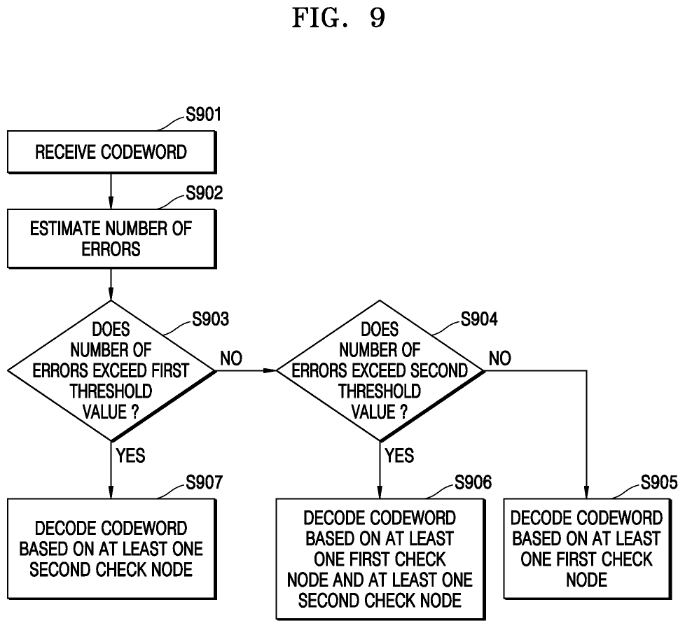

FIG. 9 illustrates an operation sequence of a decoder according to embodiments. In embodiments, the decoder may correspond to, for example, a decoder included in the ECC logic 19, for example the G-LDPC decoder 30.

In operation S901, the decoder may receive a codeword. For example, the decoder may receive the codeword from a memory device 20.

In operation S902, the decoder may estimate the number of errors. For example, the decoder may estimate the number of bits in which errors have occurred, in the received codeword.

In operation S903, the decoder may determine whether the number of errors exceeds a first threshold value. For example, the decoder may determine whether the number of bits in which the errors have occurred exceeds the first threshold value. The first threshold value may be predetermined, adaptively determined by the decoder according to the circumstances, or received from the outside, for example from the outside of the G-LDPC decoder 30, the outside of the ECC logic 19, or the outside of the memory controller 10.

In operation S904, based on the number of errors not exceeding a threshold value (NO at operation S903), the decoder may determine whether the number of errors exceeds a second threshold value. The second threshold value may be predetermined, adaptively determined by the decoder according to the circumstances, or received from the outside, for example from the outside of the G-LDPC decoder 30, the outside of the ECC logic 19, or the outside of the memory controller 10. In embodiments the first threshold value may be greater than the second threshold value.

In operation S905, based on the number of errors not exceeding the second threshold value (NO at operation S904), the decoder may decode the codeword based on the at least one first check node 72. Specifically, based on the number of errors not exceeding the second threshold value, the decoder may decode the codeword by using only a first parity check matrix 61 of an LDPC code having an SPC code as a condition.

In operation S906, based on the number of errors exceeding the second threshold value (YES at operation S903), the decoder may decode the codeword based on the at least one first check node 72 and at least one second check node 73. Specifically, based on the number of errors not exceeding the first threshold value and exceeding the second threshold value, the decoder may decode the codeword by simultaneously using the first parity check matrix 61 of the LDPC code having the SPC code as the condition and a second parity check matrix 62 of a G-LDPC code having, as a condition, a code different from the SPC code.

In operation S907, based on the number of errors exceeding the first threshold value (YES at operation S903), the decoder may decode the codeword based on the at least one second check node 73. Specifically, based on the number of errors exceeding the first threshold value, the decoder may decode the codeword by using only the second parity check matrix 62 of the G-LDPC code having, as the condition, the code different from the SPC code.

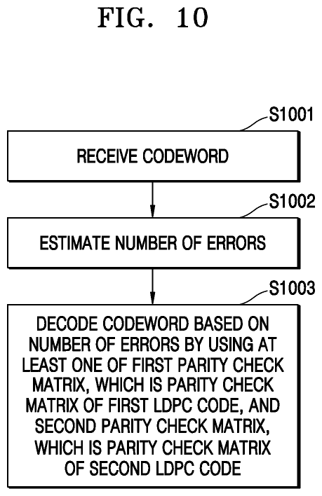

FIG. 10 illustrates an operation sequence of a decoder according to embodiments. FIG. 10 is described below with reference to FIGS. 5 and 6

In operation S1001, the decoder may receive a codeword. In operation S1002, the decoder may estimate the number of errors in the received codeword. In operation S1003, the decoder may decode the codeword based on the estimated number of errors by using at least one of a first parity check matrix 61 and a second parity check matrix 62. The first parity check matrix 61 may be a parity check matrix of a first LDPC code, and the second parity check matrix 62 may be a parity check matrix of a second LDPC code.

For example, the decoder may decode the codeword based on the first parity check matrix 61 when the estimated number of errors is less than a first threshold value, and decode the codeword based on the first parity check matrix 61 and the second parity check matrix 62 when the estimated number of errors is greater than the first threshold value. When the estimated number of errors is greater than the first threshold value, each of the first check node 72 and the second check node 73 may receive soft information from the variable node 71, and the decoder may calculate new soft information based on the received soft information. When the estimated number of errors is greater than the first threshold value, the decoder may calculate new soft information by using information received by the variable node 71 from the outside, soft information received from the first check node 72, and soft information received from the second check node 73. While decoding proceeds, the above-described calculations may be repeated several times. A size of the soft information received from the second check node 73 may be adaptively changed based on at least one of a connection state of a third parity check matrix including the first parity check matrix 61 and the second parity check matrix 62, the estimated number of errors, the number of update iterations, a decoding progress state, and an update period. The information received by the variable node 71 from the outside may include any one of hard information and soft information.

As another example, the decoder may decode the codeword based on the first parity check matrix 61 when the estimated number of errors is less than or equal to the first threshold value, decode the codeword based on the first parity check matrix 61 and the second parity check matrix 62 when the estimated number of errors is greater than the first threshold value and less than or equal to a second threshold value, and decode the codeword based on only the second parity check matrix 62 when the estimated number of errors is greater than the second threshold value.

The first parity check matrix 61 may be based on a first code (or first code type), and the second parity check matrix 62 may be based on any one of the first code (or first code type), and a second code (or second code type) that is different the first code (or first code type). For example, the first parity check matrix 61 may use, as a condition, an SPC code that becomes or produces zero (0) as a result of an XOR operation on bits of variable nodes associated with the first check node 72. As another example, the second parity check matrix 62 may use, as a condition, any one of a Hamming code, an extended Hamming code, a BCH code, a polar code, and an RS code. Referring to FIG. 5, the variable node 71 of the first parity check matrix 61 and the variable node 71 of the second parity check matrix 62 may be common.

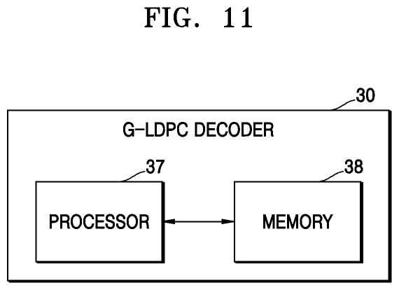

FIG. 11 illustrates a decoder according to embodiments. FIG. 11 is described with reference to FIGS. 5 and 6.

Referring to FIG. 11, a G-LDPC decoder 30 according to embodiments may include a processor 37 and a memory 38. The memory 38 may store at least one decoding parameter and be operatively connected to the processor 37. The processor 37 may receive a codeword, estimate the number of errors in the received codeword, and decode the codeword based on the estimated number of errors by using at least one of a first parity check matrix 61, which is a parity check matrix of a first LDPC code, and a second parity check matrix 62, which is a parity check matrix of a second LDPC code.

A first parity check matrix may be based on a first code (or first code type), and the second parity check matrix may be based on any one of the first code (or first code type) and a second code (or second code type) different from the first code (or first code type). The first parity check matrix 61 may use an SPC code that becomes or produces zero (0) as a result of an XOR operation on bits of variable nodes associated with a first check node. The second parity check matrix 62 may use any one of a Hamming code, an extended Hamming code, a BCH code, a polar code, and an RS code.

The processor 37 may decode the codeword based on the first parity check matrix 61 when the estimated number of errors is less than a first threshold value, and decode the codeword based on the first parity check matrix 61 and the second parity check matrix 62 when the estimated number of errors is greater than the first threshold value. The processor 37 may perform operations on a first check node 72 of the first parity check matrix 61, a second check node 73 of the second parity check matrix 62, and a variable node 71. Based on the estimated number of errors being greater than the first threshold value, the first check node 72 of the first parity check matrix 61 and the second check node 73 of the second parity check matrix 62 may each receive soft information from the variable node 71, and new soft information may be calculated based on the received soft information. Based on the estimated number of errors being greater than the first threshold value, new soft information may be calculated by using information received by the variable node 71 from the outside, soft information received by the variable node 71 from the first check node 72, and soft information by the variable node 71 from the second check node 73. A size of the soft information received by the variable node 71 from the second check node 73 may be adaptively changed based on at least one of a connection state of a third parity check matrix including the first parity check matrix 61 and the second parity check matrix 62, the estimated number of errors, the number of update iterations, a decoding progress state, and an update period.

While embodiments have been particularly shown and described with reference to embodiments thereof, it will be understood that various changes in form and details may be made therein without departing from the spirit and scope of the following claims.

What is claimed is:

1. A decoding method comprising:
receiving a codeword;
estimating a number of errors included in the received codeword; and
decoding the codeword based on the estimated number of errors using at least one of a first parity check matrix and a second parity check matrix,
wherein the first parity check matrix corresponds to a first low-density parity check (LDPC) code, and the second parity check matrix corresponds to a second LDPC code, and
wherein the first parity check matrix is based on a first code type, and the second parity check matrix is based on a second code type different from the first code type.

2. The method of claim 1, wherein the first parity check matrix is based on a single parity check (SPC) code which produces zero (0) as a result of an exclusive OR (XOR) operation performed on bits of variable nodes associated with a first check node.

3. The method of claim 2, wherein the second parity check matrix is based on one of a Hamming Code, an extended Hamming code, a Bose-Chaudhuri-Hocquenghem (BCH) code, a polar code, and a Reed-Solomon (RS) code.

4. The method of claim 1, wherein the first parity check matrix and the second parity check matrix share a variable node.

5. The method of claim 1, wherein the decoding of the codeword comprises:
based on the estimated number of errors being less than a first threshold value, decoding the codeword using the first parity check matrix and without using the second parity check matrix, and
based on the estimated number of errors being greater than the first threshold value, decoding the codeword using the first parity check matrix and the second parity check matrix.

6. The method of claim 5, wherein based on the estimated number of errors being greater than the first threshold value, the decoding of the codeword further comprises:
receiving, by each of a first check node of the first parity check matrix and a second check node of the second parity check matrix, soft information from a variable node, and
calculating new soft information based on the received soft information.

7. The method of claim 6, further comprising, based on the estimated number of errors being greater than the first threshold value, calculating the new soft information using information received by the variable node from an outside, soft information received by the variable node from the first check node, and soft information received by the variable node from the second check node.

8. The method of claim 7, wherein a size of the soft information received by the variable node from the second check node is adaptively changed based on at least one of a connection state of a third parity check matrix including the first parity check matrix and the second parity check matrix, the estimated number of errors, a number of update iterations, a decoding progress state, and an update period.

9. The method of claim 7, wherein the information received by the variable node from the outside comprises one of hard information and soft information.

10. The method of claim 1, wherein the decoding of the codeword comprises:
based on the estimated number of errors being less than or equal to a first threshold value. decoding the codeword using the first parity check matrix and without using the second parity check matrix,
based on the estimated number of errors being greater than the first threshold value and less than or equal to a second threshold value, decoding the codeword using the first parity check matrix and the second parity check matrix, and
based on the estimated number of errors being greater than the second threshold value, decoding the codeword based on the second parity check matrix and without using the first parity check matrix.

11. A decoder comprising:
a memory configured to store at least one decoding parameter; and
at least one processor operatively connected to the memory, and configured to:
receive a codeword,
estimate a number of errors in the received codeword, and
decode the codeword based on the estimated number of errors using at least one of a first parity check matrix and a second parity check matrix,
wherein the first parity check matrix corresponds to a first low-density parity check (LDPC) code, and the second parity check matrix corresponds to a second LDPC code, and
wherein the first parity check matrix is based on a first code type, and the second parity check matrix is based on a second code type different from the first code type.

12. The decoder of claim 11, wherein the first parity check matrix is based on a single parity check (SPC) code that produces zero (0) as a result of an exclusive OR (XOR) operation performed on bits of variable nodes associated with a first check node.

13. The decoder of claim 12, wherein the second parity check matrix is based on one of a Hamming code, an extended Hamming code, a Bose-Chaudhuri-Hocquenghem (BCH) code, a polar code, and a Reed-Solomon (RS) code.

14. The decoder of claim 11, wherein the first parity check matrix and the second parity check matrix share a variable node.

15. The decoder of claim 11, wherein based on the estimated number of errors being less than a first threshold value, the at least one processor is further configured to decode the codeword using the first parity check matrix and without using the second parity check matrix, and
wherein based on the estimated number of errors being greater than the first threshold value, the at least one processor is further configured to decode the codeword using the first parity check matrix and the second parity check matrix.

16. The decoder of claim 15, wherein based on the estimated number of errors being greater than the first threshold value, a first check node of the first parity check matrix and a second check node of the second parity check matrix receive soft information from a variable node, and the at least one processor is further configured to calculate new soft information based on the received soft information.

17. The decoder of claim 16, wherein based on the estimated number of errors being greater than the first threshold value, the processor is further configured to calculate the new soft information using information received by the variable node from the outside, soft information received from the first check node, and soft information received from the second check node.

18. The decoder of claim 17, wherein a size of the soft information received from the second check node is adaptively changed based on at least one of a connection state of a third parity check matrix including the first parity check matrix and the second parity check matrix, the estimated number of errors, a number of update iterations, a decoding progress state, and an update period.

19. A memory controller comprising:
a memory configured to store at least one decoding parameter; and
an error correction circuit configured to:
receive a codeword,
estimate a number of errors in the received codeword, and
decode the codeword based on the estimated number of errors using at least one of a first parity check matrix and a second parity check matrix,
wherein the first parity check matrix corresponds to a first low-density parity check (LDPC) code, and the second parity check matrix corresponds to a second LDPC code,
wherein the first parity check matrix is based on a first code type, and the second parity check matrix is based on a second code type different from the first code type.

20. The memory controller of claim 19, wherein the first parity check matrix is based on a single parity check (SPC) code that produces zero (0) as a result of an exclusive OR (XOR) operation performed on bits of variable nodes associated with a first check node,
wherein the second parity check matrix is based on one of a Hamming Code, an extended Hamming code, a Bose-Chaudhuri-Hocquenghem (BCH) code, a polar code, and a Reed-Solomon (RS) code,
wherein the first parity check matrix and the second parity check matrix share a variable node,
wherein based on the estimated number of errors being less than a first threshold value, the error correction circuit is further configured to decode the codeword using the first parity check matrix and without using the second parity check matrix, and
wherein based on the estimated number of errors being greater than the first threshold value, the error correction circuit is further configured to decode the codeword using the first parity check matrix and the second parity check matrix.
